(19) United States
(12) Patent Application Publication
(10) Pub. No.: US 2007/0117376 A1
(43) Pub. Date: May 24, 2007

(54) Method for fabricating a semiconductor device

(75) Inventor: Hyun Soo Shin, Eumseong-gun (KR)

Correspondence Address: MCKENNA LONG & ALDRIDGE LLP;Song K. Jung, 1900 K Street, N.W., Washington, DC, 20006, US

(73) Assignee: DONGBUANAM SEMICONDUCTOR INC., Seoul (KR)

(21) Appl. No.: 11/320,679

(22) Filed: Dec. 30, 2005

(30) Foreign Application Priority Data
Nov. 24, 2005 (KR) 10-2005-0112999

(51) Int. Cl. H01L 21/44; H01L 21/4763

(52) U.S. Cl. 438/637

(57) ABSTRACT

A method for fabricating a semiconductor device is disclosed. The method prevents line contact defects and overhangs associated with a barrier metal layer. The method includes forming a PMD layer on a semiconductor substrate including a terminal for the semiconductor device and forming a first contact hole by removing the PMD layer positioned over the terminal of the semiconductor device. Ions are implanted in at least portions of the PMD layer corresponding to corners associated with the contact hole. The comers of the PMD layer are rounded by etching the portions of the PMD layer that correspond to the contact hole. A metal line is formed by depositing a metal layer on the PMD layer including the contact hole and selectively removing portions of the metal layer.

This application claims the benefit of Korean Patent Application No. P2005-0112999, filed on Nov. 24, 2005, which is hereby incorporated by reference as if fully set forth herein.

### BACKGROUND OF THE INVENTION

1. Field of the Invention

The present invention relates to a method for fabricating a semiconductor device, and more particularly, to a method for forming a semiconductor device to prevent overhangs and overhanging associated with a contact hole having a small size and an aspect ratio above or greater than 4 to 1.

2. Discussion of the Related Art

While a semiconductor device is small in size, a metal line has increased line width and thickness. Also, an aspect ratio is associated with a contact hole and the connection of metal lines. Accordingly, a gap-fill process for filling a contact hole with a metal line is challenging.

When a contact hole has an aspect ratio of 3 to 1, there are few problems associated with the gap-fill process of the related art. However, if the semiconductor device has a small size and a high aspect ratio associated with the contact hole, it is difficult to completely fill the contact hole with the metal line. That is, the contact hole has a void when filled with the metal line, causing a defect of a semiconductor device.

Hereinafter, a method for fabricating a semiconductor device according to the related art will be described with reference to the accompanying drawings.

FIGS. 1A to 1F are cross sectional views showing a method for fabricating a semiconductor device according to the related art.

As shown in FIG. 1A, a gate insulating layer and a conductive material layer are sequentially deposited and patterned on a semiconductor substrate 1, and then an impurity ion implantation process is performed to the semiconductor substrate 1, thereby forming a semiconductor device on the semiconductor substrate 1.

For example, the semiconductor substrate 1 is defined with an active region and a field region. In this state, the gate insulating layer and a polysilicon layer for formation of a gate electrode are deposited and patterned to form the gate electrode. Then, impurity ions are implanted to the semiconductor substrate using the gate electrode as a mask, thereby forming source and drain regions of a transistor.

Then, a refractory metal layer, for example, titanium Ti, cobalt Co, nickel Ni or tungsten W, is deposited on an entire surface of the semiconductor substrate 1 including the semiconductor device. After that, a salicide process is performed to the deposited refractory metal layer, thereby forming a metal silicide layer 2 on the surface of the gate electrode, and the source and drain regions.

Subsequently, a barrier insulating layer SiN 3 is deposited on the metal silicide layer 2, and then an oxide layer such as BPSG or USG is deposited on the barrier insulating layer SiN 3 to form a PMD (Pre-Metal Dielectric) layer 4.

Referring to FIG. 1B, a photoresist 5 is deposited on the PMD layer 4, and is then patterned by exposure and development to expose the PMD layer 4 corresponding to a portion for forming a contact hole.

As shown in FIG. 1C, the PMD layer 4 is etched by RIE (Reactive Ion Etching) using the patterned photoresist 5 as a mask. Then, a cleaning process using sulfuric acid is performed so as to remove the photoresist 5 and a byproduct generated in the etching process.

Referring to FIG. 1D, the barrier insulating layer 3 is etched by RIE (Reactive Ion Etching) using the etched PMD layer 4 as a mask, thereby forming the contact hole.

As shown in FIG. 1E, a barrier metal layer 6 is deposited on an entire surface of the PMD layer 4 including the contact hole. At this time, if the semiconductor device has a size below 130 nm grade and the contact hole has a small size and a high aspect ratio, the barrier metal layer 6 may overhang in the comers that correspond to or define the contact hole.

In this case, the barrier metal layer 6 is provided to maintain the stable adherence between the PMD layer 4 and a tungsten layer for formation of a metal line.

As shown in FIG. 1F, a metal layer 7 of tungsten is deposited on the entire surface of the semiconductor substrate including the barrier metal layer 6, and is then selectively removed to completely fill the inside of the contact hole, thereby forming the metal line.

As mentioned above, the barrier metal layer 6 overhangs at comers corresponding to the contact hole. As a result, it is difficult to completely fill the contact hole with the metal layer, thereby causing a void.

The method for fabricating the semiconductor device according to the related art has the following disadvantages.

In the case of a semiconductor device being below 130 nm grade, the contact hole has a small size and a high aspect ratio. That is, when depositing the barrier metal layer, the barrier metal layer may have overhangs at comers corresponding to the contact hole.

Accordingly, it is difficult to completely fill the contact hole with the metal layer, thereby causing the void. As a result, the defect of line may be generated in the semiconductor device.

### SUMMARY OF THE INVENTION

Accordingly, the present invention is directed to a method for fabricating a semiconductor device that substantially obviates one or more problems due to limitations and disadvantages of the related art.

An object of the present invention is to provide a method for fabricating a semiconductor device to prevent overhangs of a barrier metal layer and line contact defects.

Additional advantages, objects, and features of the invention will be set forth in part in the description which follows and in part will become apparent to those having ordinary skill in the art upon examination of the following or may be learned from practice of the invention. The objectives and other advantages of the invention may be realized and attained by the structure particularly pointed out in the written description and claims hereof as well as the appended drawings.

To achieve these objects and other advantages and in accordance with the purpose of the invention, as embodied and broadly described herein, a method for fabricating a semiconductor device includes forming a PMD layer on a semiconductor substrate including a terminal for the semiconductor device; forming a contact hole by removing the PMD layer positioned over the terminal; implanting ions in the PMD layer at corners corresponding to the contact hole; rounding the corners by etching the PMD layer at comers corresponding to the contact hole; and forming a metal line by depositing a metal layer on the PMD layer including the contact hole and selectively removing portions of the metal layer.

In another aspect of the present invention, a method for fabricating a semiconductor device includes forming a pad insulating layer on a semiconductor substrate including a terminal for the semiconductor device; forming a PMD layer on the pad insulating layer; forming a contact hole by removing the PMD layer positioned over the terminal; implanting ions in the PMD layer at comers of the PMD layer corresponding to the contact hole; etching the pad insulating layer using the PMD layer as a mask, and rounding the PMD layer corresponding to the comers of the contact hole by etching; forming a barrier metal layer on the PMD layer including the contact hole; and forming a metal line by depositing a metal layer on the barrier metal layer and selectively removing portions of the metal layer.

At this time, the ions are slantingly implanted in the PMD layer at comers of the PMD layer corresponding to the contact hole.

Also, the ions include intrinsic semiconductor ions.

Further, the intrinsic semiconductor ions include silicon Si ions or germanium Ge ions.

Also, the ions include inactive ions.

In this case, the inactive ions include argon Ar ions or xenon Xe ions.

The ions include germanium Ge ions or xenon Xe ions.

Also, the ion implantation energy is maintained between 1 KeV and 200 KeV.

Also, the ion dose is about 1×10¹¹ to 1×10¹⁶ ions/cm².

Then, a critical angle of implanting the ions is determined to be in a range of 0˜70 degrees.

It is to be understood that both the foregoing general description and the following detailed description of the present invention are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this application, illustrate embodiment(s) of the invention and together with the description serve to explain the principle of the invention. In the drawings:

FIGS. 1A, 1B, 1C, 1D, 1E, and 1F are cross sectional views showing a method for fabricating a semiconductor device according to the related art;

FIGS. 2A, 2B, 2C, 2D, 2E, and 2F are cross sectional views showing a method for fabricating a semiconductor device according to the present invention;

FIG. 3 is a cross sectional view showing a CMOS image sensor according to the present invention; and

FIG. 4 is a cross sectional view showing a flash memory device according to the present invention.

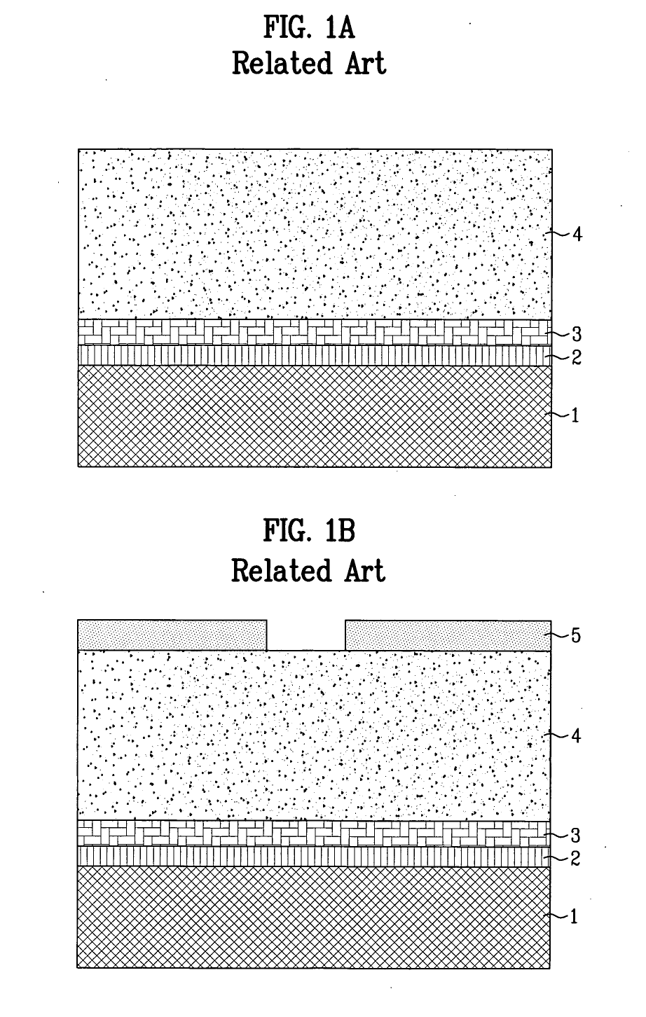

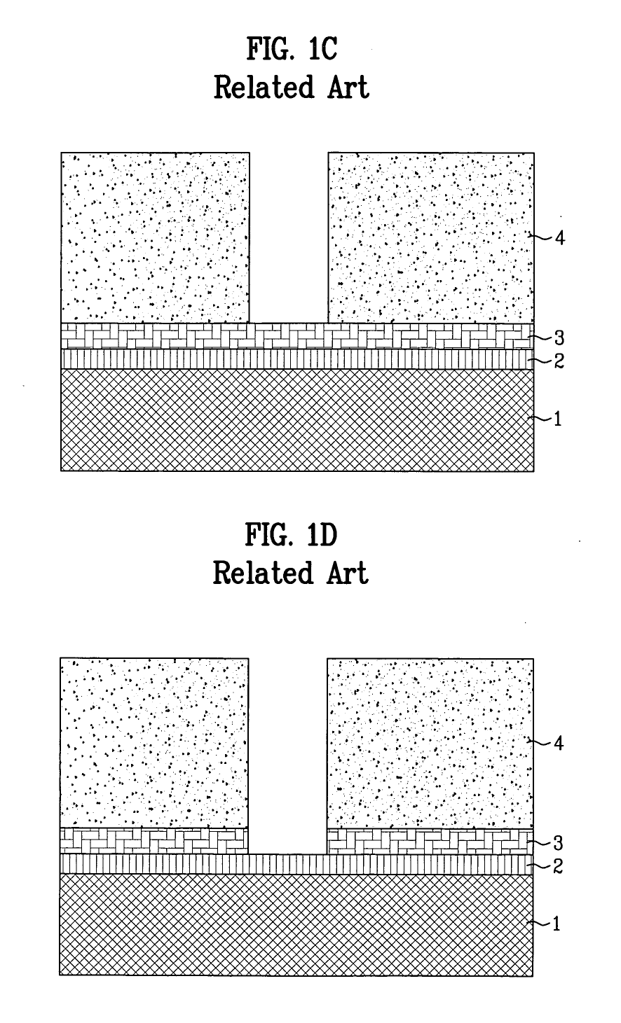

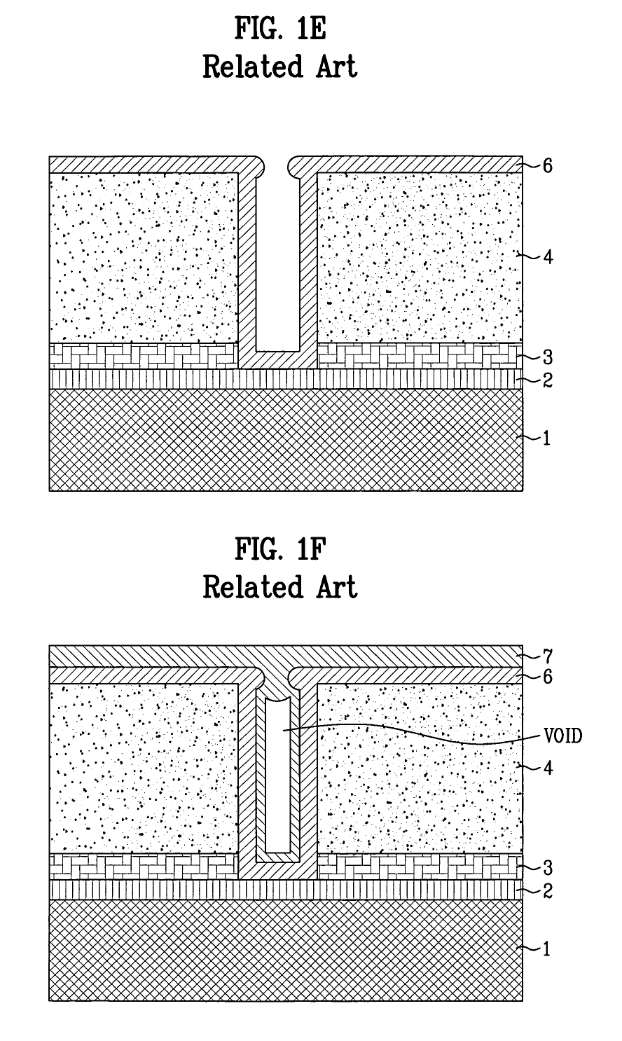

### DETAILED DESCRIPTION OF THE ILLUSTRATED EMBODIMENTS

Reference will now be made in detail to the preferred embodiments of the present invention, examples of which are illustrated in the accompanying drawings. Wherever possible, the same reference numbers will be used throughout the drawings to refer to the same or like parts.

Hereinafter, a method for fabricating a semiconductor device according to the present invention will be described with reference to the accompanying drawings.

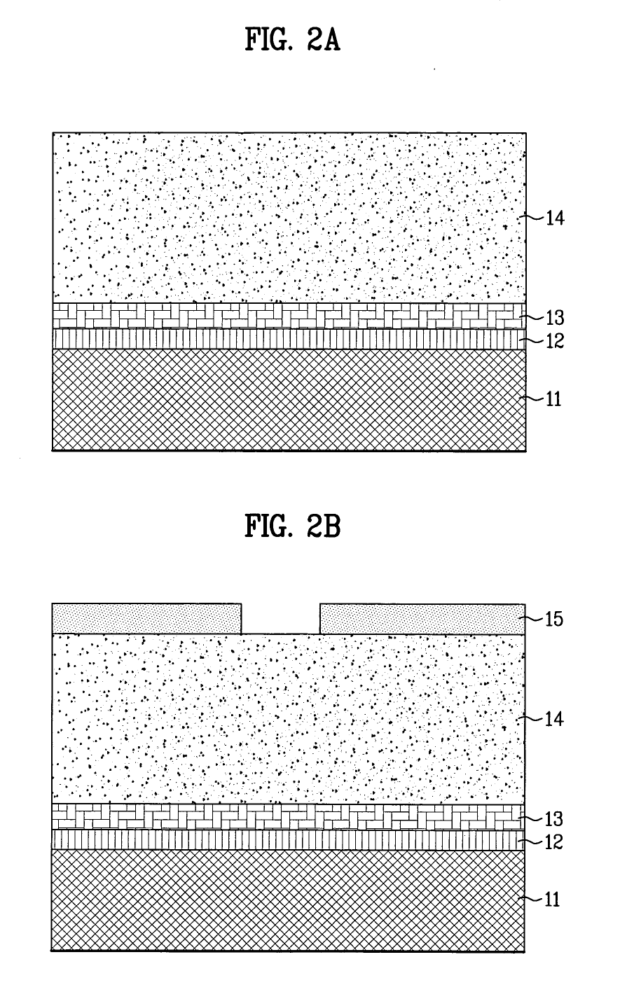

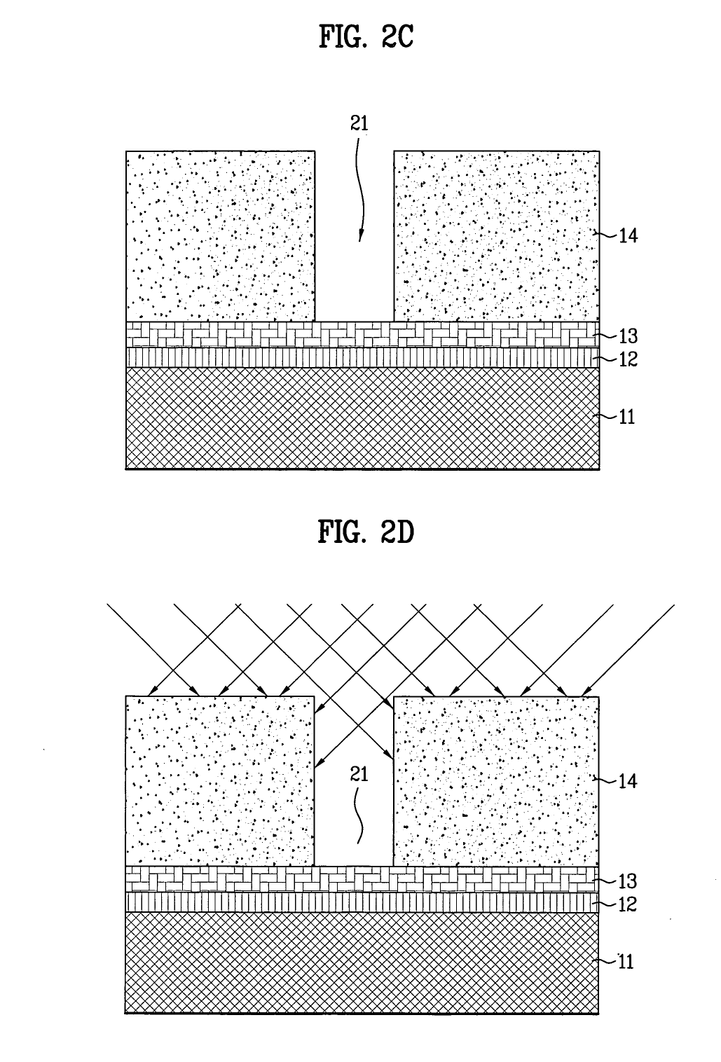

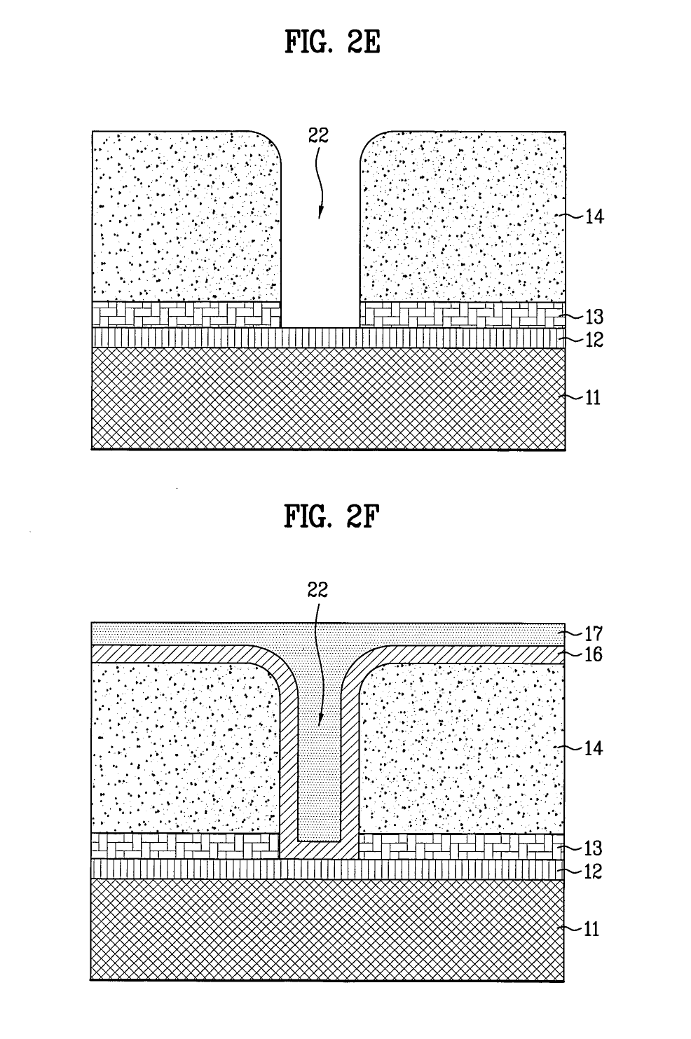

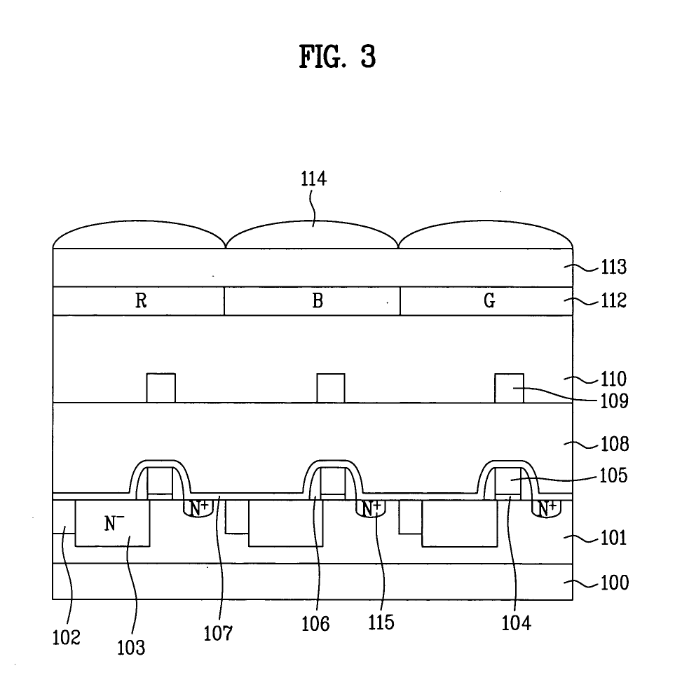

FIGS. 2A to 2F are cross sectional views showing a method for fabricating a semiconductor device according to the present invention.

As shown in FIG. 2A, a gate insulating layer and a conductive material layer are deposited and patterned on a semiconductor substrate 11, and then impurity ions are implanted in the semiconductor substrate 11, to form a semiconductor device on the semiconductor substrate 11.

For example, the semiconductor substrate 11 is defined with an active region and a field region. In this state, the gate insulating layer and a polysilicon layer for formation of a gate electrode are deposited and patterned on the semiconductor substrate corresponding to the active region, thereby forming the gate electrode. After using the gate electrode as a mask, the impurity ions are implanted to the active region of the semiconductor substrate, thereby forming source and drain regions of a transistor.

Then, a refractory metal layer, for example, titanium Ti, cobalt Co, nickel Ni or tungsten W, is deposited on an entire surface of the semiconductor substrate 11 including the semiconductor device. After that, a salicide process is performed to the deposited refractory metal layer, thereby forming a metal silicide layer 12 on the surface of the gate electrode, and the source and drain regions.

Subsequently, a barrier insulating layer SiN 13 is deposited on the metal silicide layer 12 and an oxide layer such as BPSG or USG is deposited on the barrier insulating layer SiN 13, thereby forming a PMD (Pre-Metal Dielectric) layer 14.

Referring to FIG. 2B, a photoresist 15 is deposited on the PMD layer 14, and is then patterned by exposure and development, to expose the PMD layer 14 corresponding to a portion for forming a contact hole.

As shown in FIG. 2C, the PMD layer 14 is etched by RIE (Reactive Ion Etching) using the patterned photoresist 15 as a mask. Then, a cleaning process using sulfuric acid is performed to remove the photoresist 15 and a byproduct generated in the etching process, thereby forming a first contact hole 21.

As shown in FIG. 2D, intrinsic semiconductor ions such as silicon Si or germanium Ge, or inactive ions such as argon Ar or xenon Xe are slantingly implanted in the PMD layer 14 at corners of the PMD layer corresponding to the first contact hole 21. Then, portions of the PMD layer 14 corresponding to the corners of the PMD layer associated with the first contact hole 21 are damaged.

At this time, an ion implantation energy is maintained between 1 KeV and 200 KeV, the ion dose is about 1×10¹¹ to 1×10¹⁶ ions/cm^{2,} and the critical angle of implanting the ions is determined to be in a range of 0˜70 degrees. By using heavy ions such as germanium Ge or xenon Xe, it is possible to improve the ion implantation efficiency. In this case, it is preferable to maintain a critical angle of 30˜60 degrees.

As shown in FIG. 2E, the barrier insulating layer 13 is etched by RIE using the etched PMD layer 14 as a mask, thereby forming a contact hole 22. When etching the barrier insulating layer 13, comers of the PMD layer 14, corresponding to the first contact hole 21, are damaged and removed such that the comers are rounded.

As shown in FIG. 2F, a barrier metal layer 16 is deposited on an entire surface of the PMD layer 14 including the contact hole 22. Even though the semiconductor device has a size below 130 nm grade and the contact hole 22 has a small size and a high aspect ratio, the barrier metal layer 16 is deposited on the entire surface of the semiconductor substrate including the contact hole 22 without overhangs since the comers of the PMD layer corresponding to the contact hole 22 are rounded.

The barrier metal layer 16 is formed so as to improve the adherence between the PMD layer 14 and a tungsten layer for formation of metal line.

Then, a metal layer 17 of tungsten is deposited on the entire surface of the semiconductor substrate including the barrier metal layer 16 to fill the inside of the contact hole 22, and is then selectively removed to form the metal line.

The above process for forming the contact hole and the metal line may be applied to a CMOS image sensor or a flash memory device.

That is, the CMOS image sensor may be classified into 3T, 4T and 5T types according to the number of transistors for unit cells. The 3T type CMOS image sensor includes one photodiode and three transistors, and the 4T type CMOS image sensor includes one photodiode and four transistors.

FIG. 3 is a cross sectional view showing a CMOS image sensor according to the present invention.

That is, a p−−-type epitaxial layer 101 grows on a p++-type semiconductor substrate 100 defined with a device isolation region and an active region (a photodiode region and a transistor region). Then, a field oxide layer 102 is formed in the device isolation region of the semiconductor substrate 100. Also, an n−−-type diffusion region 103 is formed in the photodiode region of the semiconductor substrate 100.

Subsequently, a gate insulating layer 104 is formed in correspondence with the transistor region of the semiconductor substrate 100, thereby forming gate electrodes 105. Also, insulating sidewalls 106 are formed at both sidewalls in each of the gate electrodes 105. In addition, source and drain regions 115 are formed in the semiconductor substrate of the active region corresponding to both sides of the gate electrode 105. Although not shown, a metal silicide layer is formed in the surface of the gate electrode 105 and the source and drain regions 115 of the transistor. Then, a diffusion stopping layer 107 is formed on an entire surface of the semiconductor substrate 100 including the gate electrode 105.

After that, a first insulating interlayer 108 is formed on the diffusion stopping layer 107, and metal lines 109 are formed on the first insulating interlayer at fixed intervals. The metal lines are formed in a multi-layered structure.

Then, a second insulating interlayer 110 is formed on the entire surface of the semiconductor substrate 100 including the metal lines 109. Also, a color filter layer 112 including red R, green G and blue B color patterns is formed on the second insulating interlayer 110, wherein the R, G and B color patterns are formed in correspondence with the respective n−−-type diffusion regions 103.

Also, a planarization layer 113 is formed on the entire surface of the semiconductor substrate 100 including the color filter layer 112. Then, micro-lenses 114 are formed on the planarization layer 113 in correspondence with the respective color patterns.

Accordingly, the transistor and photodiode regions for the unit cell are formed, and the metal lines for driving the unit cell are formed. When forming the contact hole for the metal lines, the contact hole and the metal lines are formed according to the method explained in FIGS. 2A to 2F.

The above process for forming the contact hole and the metal lines may be applied to a flash memory device.

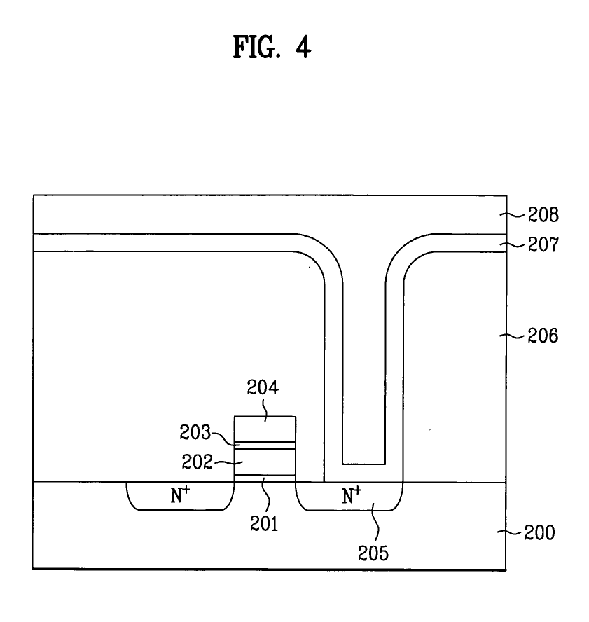

FIG. 4 is a cross sectional view showing a flash memory device according to the present invention.

First, a p-type semiconductor substrate 200 is defined with an active region (memory cell region) and a device isolation region. Then, a field oxide layer (not shown) is formed in the device isolation region of the p-type semiconductor substrate 200. In the memory cell region of the semiconductor substrate 200, there are a tunneling insulating layer 201, a floating gate 202, an insulating interlayer 203 and a control gate 204 stacked in sequence, thereby forming a gate region of a stacked type flash memory device. Then, n-type impurity ions are implanted to the semiconductor substrate 200 corresponding to both sides of the gate region, to form source and drain regions 205. In addition, a metal silicide layer may be formed in the surface of the source and drain regions 205.

After that, a PMD layer 206 is formed on an entire surface of the semiconductor substrate 200 including the gate region, and is then selectively removed from the portion corresponding to the source and drain regions 205, thereby forming a contact hole.

At this time, as shown in FIG. 2D and FIG. 2E, after ions are implanted in at least the comers of the PMD layer corresponding to the contact hole, the comers are damaged and etched such that the comers associated with the contact hole are rounded.

Then, a barrier metal layer 207 and a metal layer 208 are sequentially deposited and selectively removed, thereby forming a bit line.

Also, after forming the contact hole in the control gate 204 according to the same method, a word line may be formed.

In the above method for fabricating the semiconductor device, it is necessary to provide the process for forming the contact hole, and for connecting the metal line to the lower part by the contact hole.

As mentioned above, the method for fabricating the semiconductor device according to the present invention has the following advantages.

When forming the contact hole, intrinsic semiconductor ions such as silicon Si or germanium Ge, or inactive ions such as argon Ar or xenon Xe are selectively implanted to at least portions associated with the contact hole, and these portions are damaged. That is, portions or comers of the PMD layer associated with the contact hole are selectively removed, whereby the comers corresponding to the contact hole are rounded.

Accordingly, in case of a semiconductor device below 130 nm grade having a contact hole of small size and a high aspect ratio, when forming the barrier metal layer, it is possible to prevent the barrier metal layer from overhanging. Thus, a void is not generated when forming the metal layer on the barrier metal layer, and the inside of the contact hole is completely filled with the metal layer. Accordingly, it is possible to prevent contact defects of the metal line.

It will be apparent to those skilled in the art that various modifications and variations can be made in the present invention without departing from the spirit or scope of the inventions. Thus, it is intended that the present invention covers the modifications and variations of this invention provided they come within the scope of the appended claims and their equivalents.

What is claimed is:

1. A method for fabricating a semiconductor device comprising:
forming a Pre-Metal Dielectric (PMD) layer on a semiconductor substrate including a terminal for the semiconductor device;
forming a contact hole by selectively removing the PMD layer positioned over the terminal;
implanting ions in the PMD layer at comers corresponding to the contact hole;
rounding the comers of the contact hole by etching the PMD layer corresponding to the comers of the contact hole; and
forming a metal line by depositing a metal layer on the PMD layer including the contact hole and selectively removing portions of the metal layer.

2. The method of claim 1, wherein the ions are slantingly implanted in the PMD layer corresponding to the comers of the contact hole.

3. The method of claim 1, wherein the ions include intrinsic semiconductor ions.

4. The method of claim 3, wherein the intrinsic semiconductor ions include silicon Si ions or germanium Ge ions.

5. The method of claim 1, wherein the ions include inactive ions.

6. The method of claim 5, wherein the inactive ions include argon Ar ions or xenon Xe ions.

7. The method of claim 1, wherein the ions include germanium Ge ions or xenon Xe ions.

8. The method of claim 1, wherein an ion implantation energy is maintained between 1 KeV and 200 KeV.

9. The method of claim 1, wherein an ion dose is about 1×10¹¹ to 1×10¹⁶ ions/cm².

10. The method of claim 1, wherein a critical angle for implanting the ions is in a range of 0˜70 degrees.

11. A method for fabricating a semiconductor device comprising:
forming a pad insulating layer on a semiconductor substrate including a terminal for the semiconductor device;
forming a Pre-Metal Dielectric (PMD) layer on the pad insulating layer;
forming a contact hole by removing the PMD layer positioned over the terminal;
implanting ions in the PMD layer at comers of the PMD layer associated with the contact hole;
etching the pad insulating layer using the PMD layer as a mask, and rounding the PMD layer at comers associated with the contact hole by etching;
forming a barrier metal layer on the PMD layer including the contact hole; and
forming a metal line by depositing a metal layer on the barrier metal layer and selectively removing the metal layer.

12. The method of claim 11, wherein the ions are slantingly implanted in the PMD layer at comers corresponding to the contact hole.

13. The method of claim 11, wherein the ions include intrinsic semiconductor ions.

14. The method of claim 13, wherein the intrinsic semiconductor ions include silicon Si ions or germanium Ge ions.

15. The method of claim 11, wherein the ions include inactive ions.

16. The method of claim 15, wherein the inactive ions include argon Ar ions or xenon Xe ions.

17. The method of claim 11, wherein the ions include germanium Ge ions or xenon Xe ions.

18. The method of claim 11, wherein an ion implantation energy is maintained between 1 KeV and 200 KeV.

19. The method of claim 11, wherein an ion dose is about 1×10¹¹ to 1×10¹⁶ ions/cm².

20. The method of claim 11, wherein a critical angle of implanting the ions is in a range of 0˜70 degrees.

21. The method of claim 1 1, further comprising: forming a metal silicide layer on the terminal.
